(19) United States
(12) Patent Application Publication
(10) Pub. No.: US 2003/0026601 A1
(43) Pub. Date: Feb. 6, 2003

(54) Vapor deposition and in-situ purification of organic molecules

(75) Inventor: Ghassan E. Jabbour, Tucson, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: The Arizona Board of Regents on behalf of The University of Arizona, Tucson, AZ (US)

(21) Appl. No.: 09/917,686

(22) Filed: Jul. 31, 2001

(51) Int. Cl. C23C 16/00; C23C 14/26

(52) U.S. Cl. 392/389; 427/248.1

(57) ABSTRACT

A process for in-situ purification of organic molecules and vapor deposition of the purified molecules involves vaporizing the organic molecules from a crude material, condensing the organic molecules on a glass wool baffle, re-vaporizing the condensed organic molecules, and depositing the re-vaporized organic molecules on a substrate. An apparatus adapted for practicing the process includes a crucible, a glass wool baffle in the crucible above the bottom of the crucible, and a heater configured to heat the crucible and glass wool baffle.

The U.S. Government has a paid-up license in this invention and the right in limited circumstances to require the patent owner to license others on reasonable terms as provided for by the terms of Contract No. 000149511319 awarded by the Office of Naval Research.

### BACKGROUND OF THE INVENTION

1. Field of the Invention

This invention relates to the purification of organic molecules. In particular, this invention relates to an apparatus and a process for both purifying and vapor depositing organic molecules.

2. Description of the Background

In recent years, display technology has been dominated by flat panel displays. The flat panel display market itself has been dominated by liquid crystal displays (LCDs). However, LCDs are being challenged by organic light emitting displays (OLEDs), which are based on electroluminescent organic materials. OLEDs thinner than LCDs have been successfully fabricated, allowing OLEDs to compete with LCDs in certain display markets, especially in the miniature display market. In addition to being thinner than LCDs, OLEDs consume less power, offer a wider viewing angle and have a faster response time than LCDs, and are readable in sunlight.

OLEDs contain a variety of passive and active devices that include thin films of electroluminescent organic materials. To satisfy device requirements, the electroluminescent organic materials must be of acceptable purity. The presence of unwanted impurities severely affects the quantum efficiency, light output and lifetime of OLED devices.

Currently, the purification of electroluminescent organic materials for device applications requires several sequential solution-based processes, and/or several sublimation or evaporation processes. Many of these processes require inert environments to minimize exposure of the electroluminescent materials to humidity and oxygen, which greatly affect charge transport properties and chemical stability of electroluminescent materials, and ultimately device performance and reliability. These processes are time consuming, require dedicated equipment and personnel, and are expensive.

A need exists for a simple, efficient and inexpensive way of purifying and forming thin films of organic molecules for use in, e.g., OLED devices.

### SUMMARY OF THE INVENTION

The present invention provides an apparatus and a process for the vapor deposition and in-situ purification of organic molecules. The apparatus includes a crucible, a baffle of glass wool in the crucible above the bottom of the crucible, and a means for heating the crucible and glass wool. An organic crude material including the desired organic molecules is placed on the bottom of the crucible and the baffle of glass wool is then placed in the crucible above the crude material. The crude material, crucible and glass wool are placed under a vacuum. The means for heating heats the crucible and glass wool, causing the desired organic molecules in the crude material to vaporize and condense in purified form on the glass wool. The heat also causes the organic molecules that condense on the glass wool to vaporize and leave the crucible. The organic molecules leaving the crucible deposit on a substrate, forming a pure film of the organic molecules. Impurities in the crude material remain as a residue on the bottom of the crucible and in the lower portion of the glass wool. The quality of films of organic molecules purified and vapor deposited from organic crude material in accordance with the present invention compares favorably with the quality of films vapor deposited from material purified by conventional processes.

### BRIEF DESCRIPTION OF THE DRAWINGS

FIGS. 1A-1C illustrate an apparatus and an in-situ process for purifying and vapor depositing organic molecules.

### DETAILED DESCRIPTION OF PREFERRED EMBODIMENTS

The present invention provides an apparatus and process for purifying and vapor depositing organic molecules contained in a crude material. Starting with crude organic materials, the present invention provides an in-situ filtering technique that permits the fabrication of OLED devices with performances comparable to those of devices made with materials purified using conventional liquid and vacuum sublimation separation techniques. Although the present invention is particularly suited for purifying and vapor depositing films of light-emitting organic molecules, the invention can be used to purify and deposit any sort of molecular material that can be sublimed or evaporated. The purified organic films can be used in a variety of passive or active device applications (e.g. sensors, thin film filters, luminescent films, etc.). The in-situ filtering technique of the present invention significantly reduces the time, effort and cost associated with the fabrication of OLED devices. Moreover, the technique cuts down on the use of inert environments needed during the purification of organic materials by conventional processes.

The following example is intended to illustrate the present invention, without limiting its field of use.

### EXAMPLE

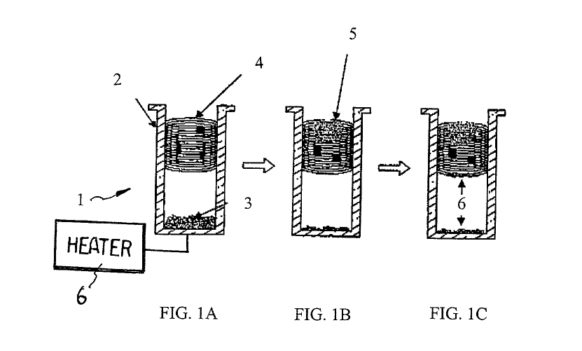

FIGS. 1A-1C show an embodiment of the apparatus of the present invention. The apparatus 1 includes a crucible 2 having an outer surface and an inner surface. The inner surface forms an interior of the crucible 2 and includes a bottom on which a crude material 3 is placed when the apparatus 1 is in use. Opposite the bottom is an opening leading from the interior of the crucible 2 to the exterior of the crucible. In embodiments, the crucible can be a hollow cylinder having one closed end forming the bottom of the cylinder. The crucible 2 is made of a refractory non-metallic material. The term “refractory” as used herein describes a material capable of withstanding a temperature at which an organic molecule will sublime or evaporate. The term “non-metallic” as used herein describes a material that is a semiconductor, an insulator, or an electrical conductor consisting essentially of an element that is not a metal. In embodiments, the crucible 2 can be made from a non-metallic material such as alumina, silicon nitride, boron nitride or graphite.

A baffle 4 of glass wool is in the interior of the crucible 2. The glass wool includes glass fibers made of a refractory material whose composition is different than the composition of the refractory material forming the crucible 2. The glass fibers can be made from glasses such as borosilicate glasses, aluminosilicate glasses and fused silica glasses. The mass of glass fibers in each cm³ of the glass wool can vary from place to place. Preferably, the mass of glass fibers in each cm³ of the glass wool is uniform throughout the glass wool. The baffle 4 can be sufficiently thin, or the glass wool can be sufficiently porous, so that a light ray can pass through the baffle 4 without touching any glass fibers. Preferably, the glass wool in the baffle 4 blocks all lines of sight through the baffle 4. The baffle 4 is positioned in the crucible 2 above the crude material 3. Preferably, the baffle 4 is positioned between the opening of the crucible 2 and a point midway between the opening of the crucible 2 and the bottom of the crucible 2. The inner surface of the crucible 2 includes a mean for supporting the glass wool above the crude material 3 on the bottom of the crucible 2. In embodiments, the inner surface of the crucible 2 includes a ledge, groove or rib for supporting the glass wool. Preferably, the glass wool presses against the inner surface of the crucible 2 and is held in place by friction.

A heater 6 schematically illustrated in FIG. 1A is provided to heat the crucible 2 and the baffle 4. The heater 6 can be any one of a variety of heaters known in the art for heating materials in vacuum systems. For example, the heater 6 can be a resistive heater encircling the crucible 2 and its inner surface. The resistive heater can include a filament of a refractory electrical conductor, such as Mo and W, encircling the crucible 2 one or more times. Passing an DC or AC electrical current through the refractory electrical conductor can heat the resistive heater, which then heats the crucible 2 and baffle 4 via conduction, convection and/or radiation processes. Alternative heaters include heat sources relying primarily on radiation, including those with a filament that does not encircle the crucible 2.

The apparatus 1 can be assembled by inserting the baffle 4 of glass wool into the interior of the crucible 2 and positioning the heater 6 around or adjacent to the crucible 2.

The apparatus 1 can be used according to the present invention in a process in which organic molecules are simultaneously purified and vapor deposited.

As shown in FIGS. 1A-1C, an organic crude material 3 is first placed on the bottom of the crucible 2. The organic crude material 3 includes desired organic molecules in a mixture with various impurities, which can be organic or inorganic. Preferably, the desired organic molecules are light-emitting organic molecules, such a electroluminescent organic molecules. The desired organic molecules can be polymers or monomers. Preferably, the desired organic molecules are monomers.

After placing the crude material 3 on the bottom of the crucible 2, the baffle 4 is installed in the crucible 2 over the crude material 3. Although the optimum amount and configuration of glass wool in the baffle 4, and the position of the baffle 4 in the crucible 2 relative to the crude material 3, will vary with the organic molecules being purified and the nature of the crude material 3, optimization of these factors is well within the skill in the art.

After installing the baffle 4 in the crucible 2, the apparatus 1 is placed under a vacuum at a pressure of less than 1 atmn. Systems for creating and maintaining a vacuum are well known in the art and will not be discussed here. Preferably, the pressure is less than 10⁻⁴ torr; more preferably, less than 10⁻⁶ torr; and even more preferably, less than 10⁻⁷ torr. Then, the heater 6 heats the crucible 2, the crude material 3, and the baffle 4. The desired organic molecules in the crude material 3 are vaporized to form a first vapor. Preferably, the vaporization is by one or more of a sublimation process and an evaporation process. The first vapor includes the desired organic molecules and traces of residual impurities. The first vapor condenses on the glass wool of baffle 4. Because baffle 4 is hot, the condensate on the glass wool re-vaporizes. Again, the vaporization is preferably by one or more of a sublimation process and an evaporation process. As shown in FIG. 1B, after condensing on and re-vaporizing from a number of glass fibers in the baffle 4, purified molecules 5 gather in the upper part of the glass wool baffle 4. As shown in FIG. 1C, the purified molecules 5 in the upper part of the baffle 4 sublime or evaporate to form a second vapor. The second vapor including the desired purified organic molecules then emerges from the baffle 4 and leaves the crucible 2. The second vapor can deposit directly on a substrate (not shown), or the second vapor can undergo further processing before it deposits on the substrate. The substrate is not limited, and can be any surface having any geometry. Preferably, the substrate is configured to form part of an OLED. A residue 6, consisting of impurities and unwanted species, remains on the bottom of the crucible 2 and in the lower part of the glass wool baffle 4.

The vaporization of the desired organic molecules from the crude material 3 and the vaporization of the desired organic molecules from the baffle 4 can take place sequentially or simultaneously. Preferably, the two vaporization processes occur simultaneously.

The heater 6 can heat the crude material 3 on the bottom of the crucible 2 and the glass wool of the baffle 4 to the same or different temperatures. Preferably, the heater 6 heats the crude material 3 and the baffle 4 to about the same temperature.

As described in the above Example, the present invention allows for the simultaneous in-situ purification and deposition of thin films of organic molecules. The quality of the thin films deposited this way compares very well to the quality of films deposited from pure starting materials. OLED devices made using the apparatus and process of the present invention can exhibit performance characteristics similar to those of OLED devices made with starting materials purified by conventional techniques.

While the present invention has been described with respect to specific embodiments, it is not confined to the specific details set forth, but includes various changes and modifications that may suggest themselves to those skilled in the art, all falling within the scope of the invention as defined by the following claims.

What is claimed is:

1. An apparatus for purifying and vaporizing organic molecules contained in a crude material, the apparatus comprising
a non-metallic crucible including an outer surface and an inner surface having a bottom configured to support the crude material;
a baffle comprising a glass wool in the crucible above the bottom; and
a heater configured to heat the crucible and the baffle.

2. The apparatus according to claim 1, wherein the crucible comprises an electrically insulating material.

3. The apparatus according to claim 1, wherein the crucible comprises a material selected from the group consisting of alumina, silicon nitride, boron nitride and graphite.

4. The apparatus according to claim 1, wherein the glass wool comprises a glass selected from the group consisting of borosilicate glasses, aluminosilicate glasses, and fused silica glasses.

5. The apparatus according to claim 1, wherein
the glass wool comprises glass fibers; and
a mass of the glass fibers in each cm³ of the glass wool is uniform throughout the glass wool.

6. The apparatus according to claim 1, wherein the glass wool blocks all lines of sight from the bottom of the crucible to an exterior of the crucible.

7. The apparatus according to claim 1, wherein
the crucible further comprises an opening to an exterior of the crucible opposite the bottom of the crucible; and
the glass wool is between the opening of the crucible and a point halfway between the opening of the crucible and the bottom of the crucible.

8. The apparatus according to claim 1, wherein the inner surface includes a support configured to support the glass wool above the bottom of the crucible.

9. The apparatus according to claim 1, wherein the heater comprises a resistive heater.

10. A film deposition process comprising
placing a crude material including organic molecules directly on a first refractory material;
vaporizing at least a portion of the organic molecules in the crude material to form a first vapor including the organic molecules;
condensing the first vapor on a second refractory material, which comprises a material having a different composition than the first refractory material, to form a condensate including the organic molecules;
vaporizing at least a portion of the organic molecules in the condensate to form a second vapor including the organic molecules; and
depositing the second vapor on a substrate.

11. The film deposition process according to claim 10, further comprising
providing an apparatus comprising
a non-metallic crucible of the first refractory material including an outer surface and an inner surface, which includes a bottom for supporting the crude material;
a baffle comprising a glass wool of the second refractory material in the crucible above the bottom of the crucible; and
a means for heating the crucible and the baffle.

12. The process according to claim 10, wherein the organic molecules include light-emitting organic molecules.

13. The process according to claim 10, wherein the organic molecules include monomers.

14. The process according to claim 10, wherein
the vaporizing at least a portion of the organic molecules in the crude material comprises heating the first refractory material; and
the vaporizing at least a portion of the organic molecules in the condensate comprises heating the second refractory material.

15. The process according to claim 14, wherein the heating the first refractory material and the heating the second refractory material each comprises heating a resistive heater.

16. The process according to claim 14, wherein the first refractory material and the second refractory material are heated to about the same temperature.

17. The process according to claim 10, wherein the vaporizing at least a portion of the organic molecules in the crude material and the vaporizing at least a portion of the organic molecules in the condensate are carried out simultaneously.

18. The process according to claim 10, wherein the vaporizing at least a portion of the organic molecules in the crude material and the vaporizing at least a portion of the organic molecules in the condensate each independently comprises at least one process selected from the group consisting of sublimation and evaporation.

19. The process according to claim 10, wherein the vaporizing at least a portion of the organic molecules in the crude material and the vaporizing at least a portion of the organic molecules in the condensate are each performed at a pressure of less than 1 atm.

20. A process for purifying organic molecules, the process comprising
placing a crude material including organic molecules directly on a first refractory material;
vaporizing at least a portion of the organic molecules in the crude material to form a first vapor including the organic molecules;
condensing the first vapor on a second refractory material, which comprises a material having a different composition than the first refractory material, to form a condensate including the organic molecules; and
vaporizing at least a portion of the organic molecules in the condensate to form a second vapor including the organic molecules.
